(19) United States
(12) Patent Application Publication
(10) Pub. No.: US 2025/0227977 A1
(43) Pub. Date: Jul. 10, 2025

(54) BACKSIDE ANGLED SOURCE/DRAIN CONTACT STRUCTURE

(71) Applicant: INTERNATIONAL BUSINESS MACHINES CORPORATION, ARMONK, NY (US)

(72) Inventors: Min Gyu Sung, Latham, NY (US); Tao Li, Slingerlands, NY (US); Ruilong Xie, Niskayuna, NY (US)

(21) Appl. No.: 18/408,633

(22) Filed: Jan. 10, 2024

(51) Int. Cl. H01L 29/417; H01L 23/528; H01L 29/40

(52) U.S. Cl. CPC H10D 64/254; H01L 23/5286; H10D 64/01

(57) ABSTRACT

Embodiments of present invention provide a semiconductor structure. The semiconductor structure includes a first source/drain (S/D) region of a first transistor and a second S/D region of a second transistor; a first backside contact metal (BCM) conductively connected to the first S/D region, the first BCM having a first longitudinal axis; and a second BCM conductively connected to the second S/D region, the second BCM having a second longitudinal axis, where the first longitudinal axis of the first BCM intersects with the second longitudinal axis of the second BCM in an acute angle. A method of forming the same is also provided.

### BACKGROUND

The present application relates to manufacturing of semiconductor integrated circuits. More particularly, it relates to backside angled source/drain contact structure and method of forming the same.

As semiconductor industry moves towards creating smaller node for semiconductor chip, field-effect-transistors (FETs) are aggressively scaled to fit into reduced footprint or real estate, which is often dictated by the node size. With increased device density, some of the contacts to the FETs such as, for example, source/drain contacts are provided through backside of the semiconductor chip, and backside power rails (BPRs) are subsequently formed to contact the source/drain contacts. In addition, backside power distribution network (BSPDN) may be formed to provide signal routing and power supply functionalities to the semiconductor device on the semiconductor chip.

However, when the BPRs are formed directly underneath and corresponding to their FETs, the short tip-to-tip distance between the BPRs will not only make the process of making such BPRs difficult, but also potentially cause short between Vdd and Vss. It is desirable and/or preferable to be able to increase or relax restriction on such tip-to-tip distance. Also, it is also preferable to increase contact area between the BPRs and the source/drain contacts.

### SUMMARY

Embodiments of present invention provide a semiconductor structure. The semiconductor structure includes a first source/drain (S/D) region of a first transistor and a second S/D region of a second transistor; a first backside contact metal (BCM) conductively connected to the first S/D region, the first BCM having a first longitudinal axis; and a second BCM conductively connected to the second S/D region, the second BCM having a second longitudinal axis, where the first longitudinal axis of the first BCM intersects with the second longitudinal axis of the second BCM in an acute angle. In other words, the first BCM and the second BCM are formed in angled directions, resulting in the spreading of distance between the first and the second BCM thereby ensuring more flexibility of forming backside power rails to contact the BCMs. By expanding the distance, the risk of electrical short between nearby BCMs is significantly reduced and consequently device yield gets improved.

In one embodiment, the first BCM is conductively connected to the first S/D region via a first backside S/D contact, the first backside S/D contact having a liner at sidewalls thereof and having a horizontal width that is substantially same as a bottom width of the first S/D region.

In another embodiment, the first BCM has a first width measured in a direction perpendicular to the first longitudinal axis, the first width being equal to or larger than the horizontal width of the first backside S/D contact.

In one embodiment, the first and the second BCM are embedded in a dielectric layer, the first longitudinal axis of the first BCM forming a first angle with a normal of the dielectric layer between 5 and 45 degrees, and the second longitudinal axis of the second BCM forming a second angle with the normal of the dielectric layer between −5 and −45 degrees.

In another embodiment, the first BCM is in contact with a first backside power rail (BPR) and the second BCM is in contact with a second BPR, a distance between the first and the second BPR is larger than a distance between the first and the second S/D region.

According to one embodiment, the semiconductor structure further includes a third S/D region of a third transistor next to the first S/D region of the first transistor, the third S/D region being on top of a placeholder, the placeholder being materially different from the first backside S/D contact. In one aspect, the semiconductor structure further includes a frontside S/D contact contacting the third S/D region of the third transistor.

In one embodiment, the first S/D region includes phosphorus-doped epitaxial silicon, and the second S/D region includes boron-doped epitaxial silicon-germanium.

Embodiments of present invention further provide a method of forming a semiconductor structure. The method includes forming a first source/drain (S/D) region on top of a first placeholder and a second S/D region on top of a second placeholder; creating a first angled opening in a dielectric layer underneath the first and the second placeholder, the first angled opening exposing the first placeholder; selectively removing the first placeholder to create a first opening extension that exposes a bottom surface of the first S/D region; filling the first opening extension with a conductive material to form a first backside S/D contact; and filling the first angled opening with the conductive material to form a first backside contact metal (BCM) conductively connected to the first S/D region via the first backside S/D contact.

According to one embodiment, the method further includes creating a second angled opening in the dielectric layer to expose the second placeholder; selectively removing the second placeholder to create a second opening extension that exposes a bottom surface of the second S/D region; filling the second opening extension to form a second backside S/D contact; and filling the second angled opening to form a second BCM conductively connected to the second S/D region via the second backside S/D contact, where the first BCM has a first longitudinal axis and the second BCM has a second longitudinal axis, the first and the second longitudinal axis form an acute angle.

In one embodiment, the dielectric layer is deposited on top of the first and the second placeholder after a set of raw placeholders are polished to create the first and the second placeholder.

In another embodiment, creating the first angled opening in the dielectric layer includes forming a hard mask on top of the dielectric layer, the hard mask having a mask opening, the mask opening having a horizontal positional offset from the first placeholder; and etching the dielectric layer in an anisotropic etch process to create the first angled opening, the first angled opening being oriented in a direction connecting the mask opening with the first placeholder.

In one embodiment, a longitudinal axis of the first angled opening forms an angle between about 5 to 45 degrees with a normal of the dielectric layer.

According to one embodiment, the method further includes forming a first backside power rail (BPR) in contact with the first BCM and a second BPR in contact with the second BCM.

According to another embodiment, the method further includes forming a third S/D region of a third transistor on top of a third placeholder and next to the first S/D region, and forming a fourth S/D region of a fourth transistor on top of a fourth placeholder and next to the second S/D region, wherein the third S/D region is contacted by a first frontside S/D contact and the fourth S/D region is contacted by a second frontside S/D contact.

### BRIEF DESCRIPTION OF THE DRAWINGS

The present invention will be understood and appreciated more fully from the following detailed description of embodiments of present invention, taken in conjunction with accompanying drawings of which:

FIG. 1 to FIG. 18 are demonstrative illustrations of cross-sectional views of a semiconductor structure at different steps of manufacturing thereof according to embodiments of present invention; and

FIG. 19 is a demonstrative illustration of a flow-chart of a method of manufacturing a semiconductor structure according to embodiments of present invention.

It will be appreciated that for simplicity and clarity purpose, elements shown in the drawings have not necessarily been drawn to scale. Further, and if applicable, in various functional block diagrams, two connected devices and/or elements may not necessarily be illustrated as being connected. In some other instances, grouping of certain elements in a functional block diagram may be solely for the purpose of description and may not necessarily imply that they are in a single physical entity, or they are embodied in a single physical entity.

### DETAILED DESCRIPTION

In the below detailed description and the accompanying drawings, it is to be understood that various layers, structures, and regions shown in the drawings are both demonstrative and schematic illustrations thereof that are not drawn to scale. In addition, for the ease of explanation, one or more layers, structures, and regions of a type commonly used to form semiconductor devices or structures may not be explicitly shown in a given illustration or drawing. This does not imply that any layers, structures, and regions not explicitly shown are omitted from the actual semiconductor structures. Furthermore, it is to be understood that the embodiments discussed herein are not limited to the particular materials, features, and processing steps shown and described herein. In particular, with respect to semiconductor processing steps, it is to be emphasized that the descriptions provided herein are not intended to encompass all of the processing steps that may be required to form a functional semiconductor integrated circuit device. Rather, certain processing steps that are commonly used in forming semiconductor devices, such as, for example, wet cleaning and annealing steps, are purposefully not described herein for economy of description.

It is to be understood that the terms “about” or “substantially” as used herein with regard to thicknesses, widths, percentages, ranges, etc., are meant to denote being close or approximate to, but not exactly. For example, the term “about” or “substantially” as used herein implies that a small margin of error may be present such as, by way of example only, 1% or less than the stated amount. Likewise, the terms “on”, “over”, or “on top of” that are used herein to describe a positional relationship between two layers or structures are intended to be broadly construed and should not be interpreted as precluding the presence of one or more intervening layers or structures.

Moreover, although various reference numerals may be used across different drawings, the same or similar reference numbers are used throughout the drawings to denote the same or similar features, elements, or structures, and thus detailed explanations of the same or similar features, elements, or structures may not be repeated for each of the drawings for economy of description. Labelling for the same or similar elements in some drawings may be omitted as well in order not to overcrowd the drawings.

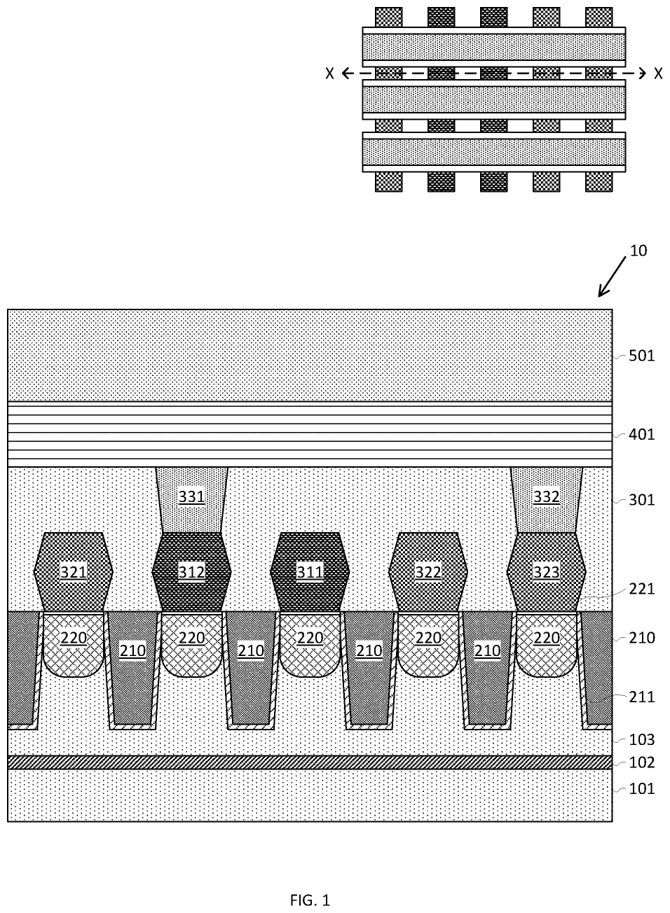

FIG. 1 is a demonstrative illustration of cross-sectional view of a semiconductor structure in a step of manufacturing thereof according to one embodiment of present invention. FIG. 1 also includes a simplified top view of the semiconductor structure with a dashed X-X line indicating where the cross-section is made. As its sole purpose is to illustrate the location of cross-section, the simplified top view may only schematically illustrate, for example, nanosheets and gates of the structure that are formed or yet to be formed.

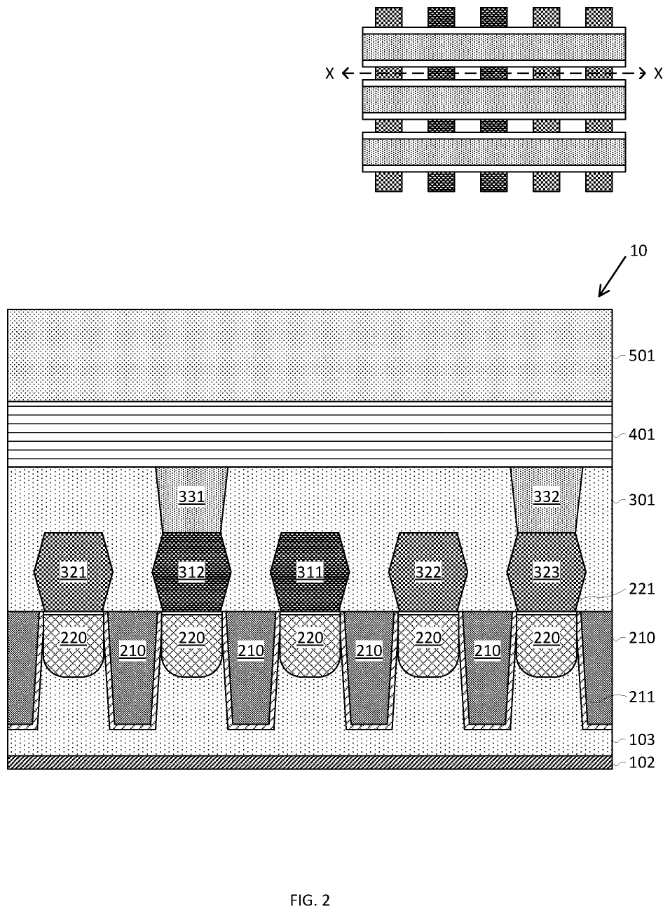

More specifically FIG. 1, and similarly FIGS. 2-18, illustrates a cross-sectional view of the semiconductor structure, which includes multiple transistors, made across S/D regions of the multiple transistors in a direction along the width of gates of the multiple transistors.

Embodiments of present invention provide receiving or providing a semiconductor structure 10 that is demonstratively illustrated here to include multiple transistors, such as nanosheet transistors, although embodiments of present invention are not limited in this aspect and may be applied to other types of transistors and/or active devices. More particularly, the semiconductor structure 10 may include a silicon (Si) substrate 101 with an etch-stop layer 102 on top thereof and a Si layer 103 on top of the etch-stop layer 102. In one embodiment, the etch-stop layer 102 may be a layer of dielectric such as silicon-nitride (SiN) or silicon-oxide (SiO₂) or may be a layer of silicon-germanium (SiGe). In another embodiment, the Si substrate 101, the etch-stop layer 102, and the Si layer 103 may collectively be a silicon-on-insulator (SOI) substrate.

The semiconductor structure 10 may also include multiple placeholders 220, with a thin etch-stop layer 221 on top thereof, embedded in the Si layer 103. In one embodiment, the etch-stop layer 221 may be a thin layer of epitaxially grown Si (epi Si) and the multiple placeholders 220 may be layers of SiGe. By strategically applying any difference in etch selectivity between SiGe of the placeholders 220 and epi Si of the etch-stop layer 221, one or more of the placeholders 220 may be selectively removed or etched away later, as being described below in more details. The multiple placeholders 220 may be insulated and/or separated by multiple shallow-trench-isolations (STIs) 210. The multiple STIs 210 may include a liner 211 lining sidewalls and bottoms thereof. The liner 211 may be made of, for example, SiN or SiO₂.

The semiconductor structure 10 may also include multiple source/drain (S/D) regions of multiple transistors, such as a first group of S/D regions 311 and 312 and a second group of S/D regions 321, 322, and 323, formed respectively on top of each of the placeholders 220 via the etch-stop layer 221. In one embodiment, the S/D regions 311 and 312 of the first group may be epitaxially grown Si, which may be doped with phosphorus (P) and thus may be S/D regions of Si: P of one or more n-type transistors. In another embodiment, the S/D regions 321, 322, and 323 of the second group may be epitaxially grown SiGe, which may be doped with boron (B) and thus may be S/D regions of SiGe: B of one or more p-type transistors.

The S/D regions 311, 312, 321, 322, and 323 may be embedded in a dielectric layer 301. One or more frontside S/D contacts may be formed in the dielectric layer 301 contacting one or more of the S/D regions. For example, a first frontside S/D contact 331 may be in contact with the S/D region 312 and a second frontside S/D contact 332 may be in contact with the S/D region 323. In one embodiment, the first and second frontside S/D contacts 331 and 332 may respectively be part of a middle-of-line (MOL) contact structure. As is illustrated in FIG. 1, no MOL contact structure is formed in contact with other S/D regions such as the S/D region 311, 321, and 322.

The semiconductor structure 10 may also include a back-end-of-line (BEOL) structure 401 formed on top of the dielectric layer 301 in contact with the one or more frontside S/D contact structures; and a carrier wafer 501 bonded onto the BEOL structure 401. With the carrier wafer 501, the semiconductor structure 10 may be ready to be processed from a backside thereof, as being described below in more details.

FIG. 2 is a demonstrative illustration of cross-sectional view of a semiconductor structure in a step of manufacturing thereof according to one embodiment of present invention. More particularly, following the step illustrated in FIG. 1, embodiments of present invention provide selectively removing the Si substrate 101 through, for example, a grinding process, a chemical-mechanical-polishing (CMP) process, and/or a selective etching process. The removal of the Si substrate 101 may stop at the etch-stop layer 102.

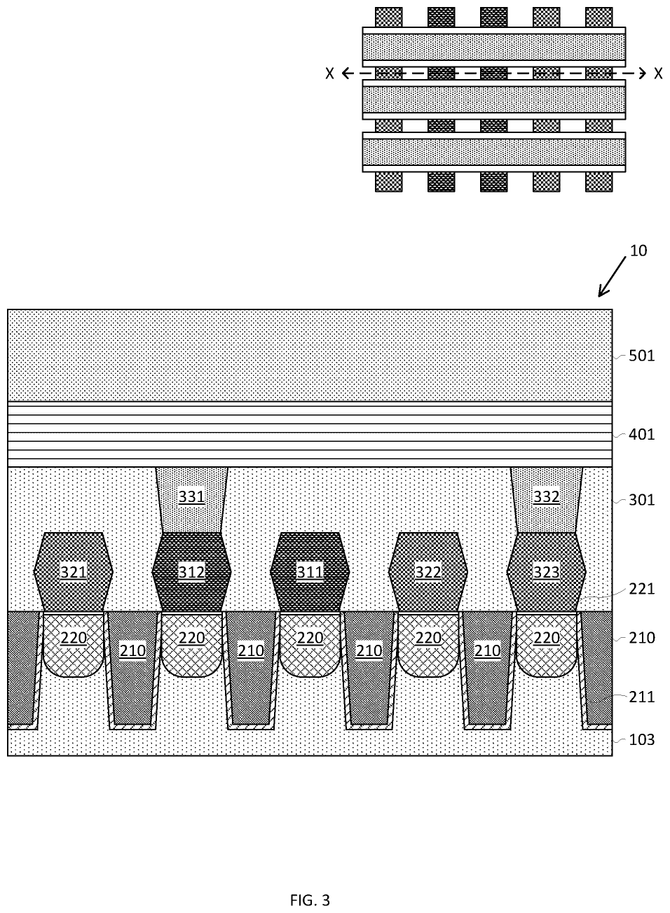

FIG. 3 is a demonstrative illustration of cross-sectional view of a semiconductor structure in a step of manufacturing thereof according to one embodiment of present invention. More particularly, following the step illustrated in FIG. 2, embodiments of present invention provide removing the exposed etch-stop layer 102 through a selective etch process such as a reactive-ion-etch (RIE) process. The removal of the etch-stop layer 102 may thus expose the Si layer 103.

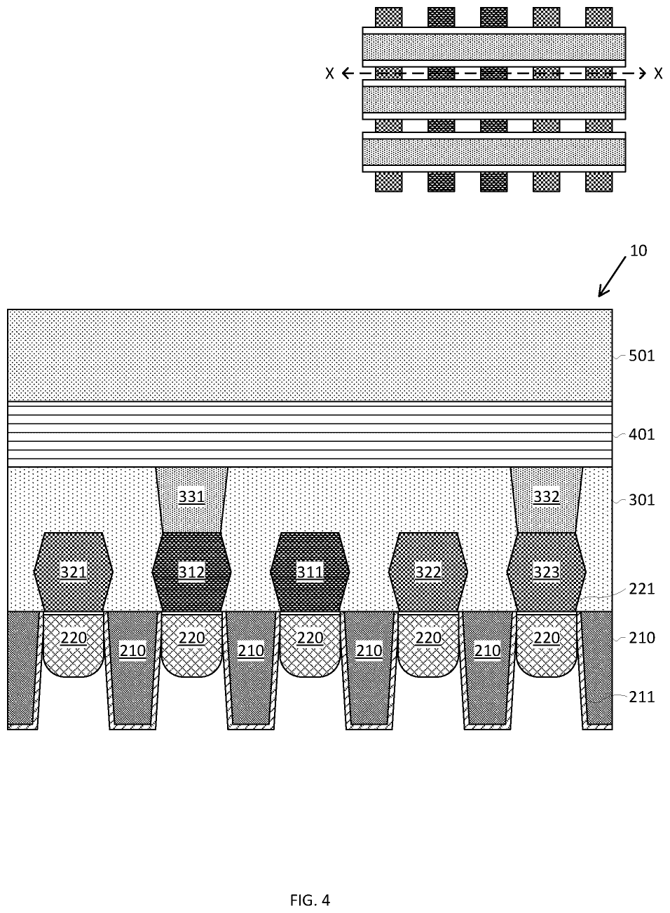

FIG. 4 is a demonstrative illustration of cross-sectional view of a semiconductor structure in a step of manufacturing thereof according to one embodiment of present invention. More particularly, following the step illustrated in FIG. 3, embodiments of present invention provide selectively removing, for example through a dry or wet etch process, the exposed Si layer 103. In one embodiment, the Si layer 103 may be substantially removed and the multiple placeholders 220 may thus be exposed. The multiple STIs 210, between the multiple placeholders 220 and being covered by the liner 211, may be exposed as well by the removal of the Si layer 103.

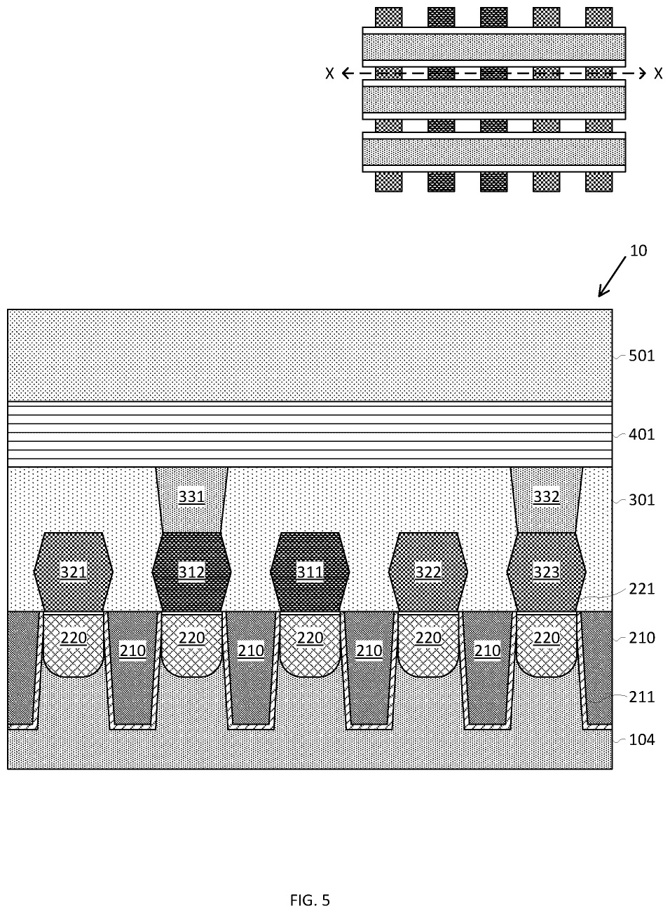

FIG. 5 is a demonstrative illustration of cross-sectional view of a semiconductor structure in a step of manufacturing thereof according to one embodiment of present invention. More particularly, following the step illustrated in FIG. 4, embodiments of present invention provide forming a layer of dielectric material on top of the exposed placeholders 220 and the STIs 210. The dielectric material may be silicon-oxide (SiO₂), for example, and may be formed through a deposition process or other suitable processes. The dielectric material may substantially fill out gaps between the STIs 210 and above the placeholders 220. Subsequently, a CMP process may be applied to planarize a top surface of the dielectric material thereby forming a dielectric layer 104.

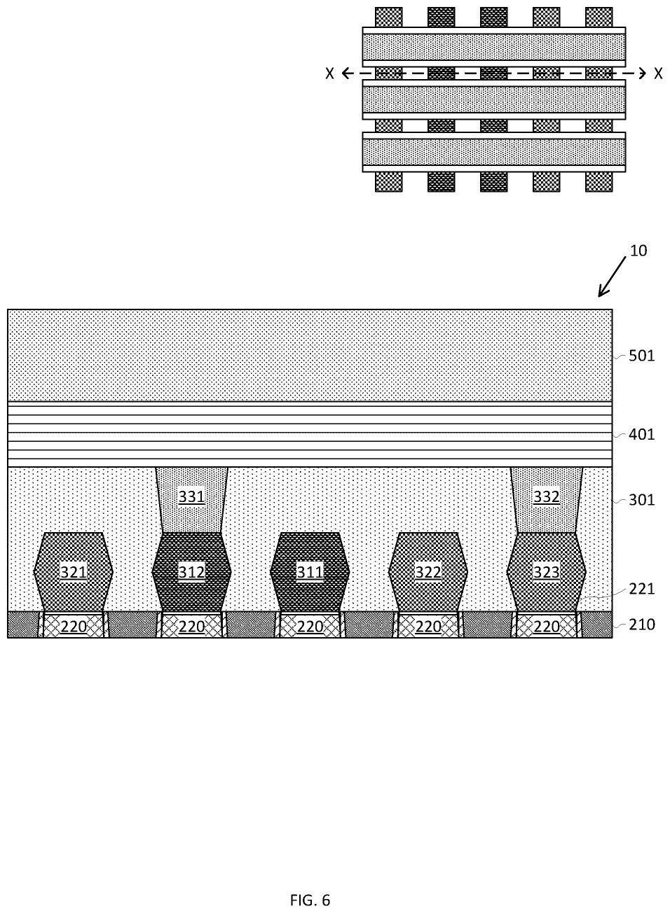

FIG. 6 is a demonstrative illustration of cross-sectional view of a semiconductor structure in a step of manufacturing thereof according to one embodiment of present invention. More particularly, following the step illustrated in FIG. 5, embodiments of present invention provide applying a CMP process to remove the dielectric layer 104 and remove a portion of the STIs 210 until the multiple placeholders 220 are exposed. In one embodiment, portions of the multiple placeholders 220 may be removed as well until most of the dielectric material of the dielectric layer 104, such as those in gaps between the placeholders 220 and the liner 211 of the STIs 210, are removed. Replacing the Si layer 103 with the dielectric layer 104 enables this CMP process to expose the multiple placeholders 220.

As is demonstrated in FIG. 6, the multiple placeholders 220 are substantially aligned, vertically, with the S/D regions 311, 312, 321, 322, and 323 and are surrounded at sidewalls by the remaining portions of the liner 211 that lines the STIs 210.

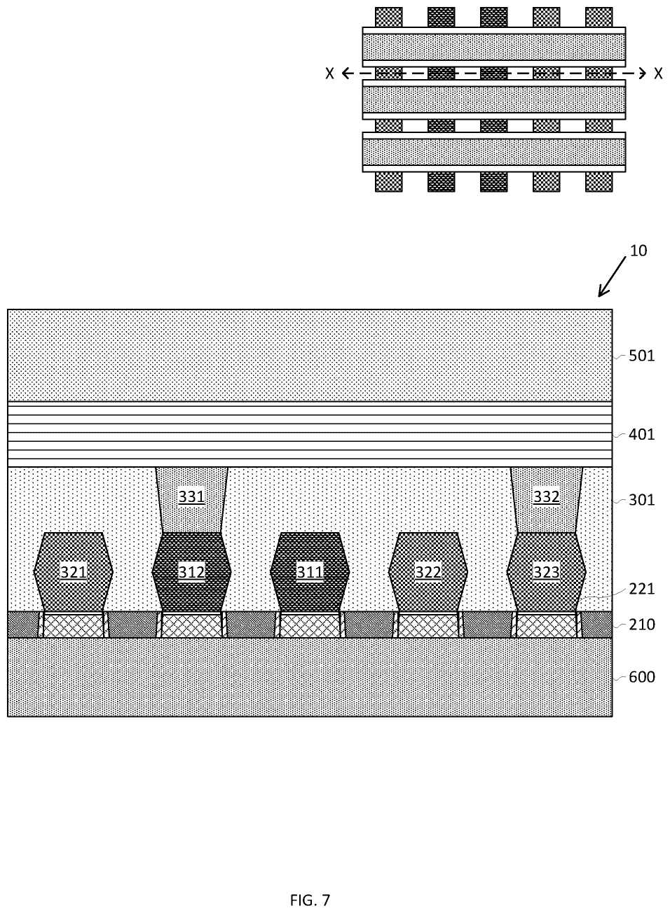

FIG. 7 is a demonstrative illustration of cross-sectional view of a semiconductor structure in a step of manufacturing thereof according to one embodiment of present invention. More particularly, following the step illustrated in FIG. 6, embodiments of present invention provide forming a dielectric layer 600 covering the exposed remaining portions of the placeholders 220 and the STIs 210. The dielectric layer 600 may be formed through a deposition process such as, for example, a chemical-vapor-deposition (CVD) process, a physical-vapor-deposition (PVD) process, and/or an atomic-layer-deposition (ALD) process. The dielectric layer 600 may be formed to have a thickness, for example, between about 100 nm and about 500 nm, sufficient to form angled openings that, as being described below in more details, may extend approximately between two adjacent S/D regions. For example, in one embodiment, the dielectric layer 600 may be deposited to have a thickness that is at least equal to, and in most cases larger than, a distance between two adjacent S/D regions, which is typically around 10 to 40 nm.

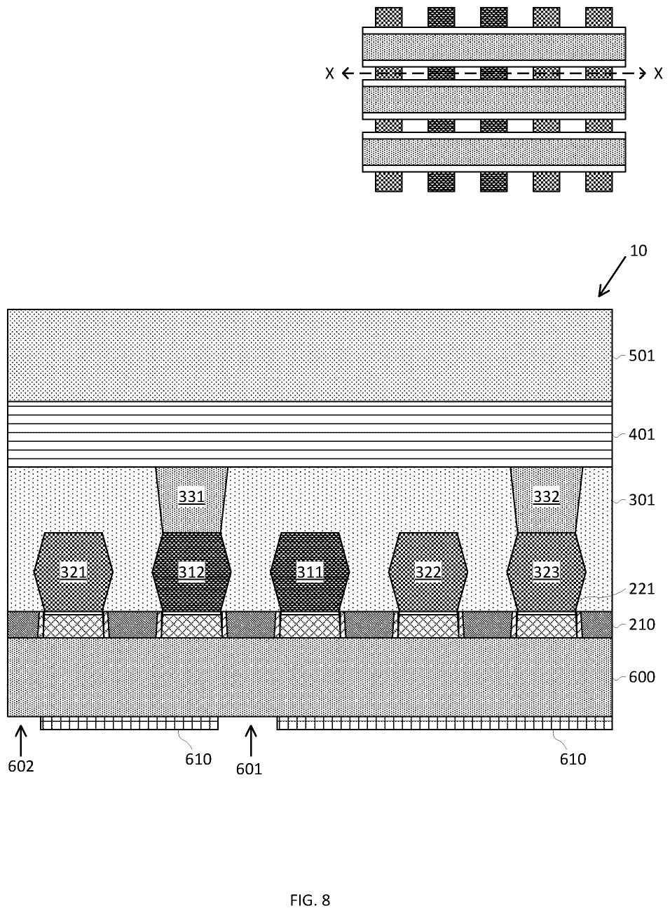

FIG. 8 is a demonstrative illustration of cross-sectional view of a semiconductor structure in a step of manufacturing thereof according to one embodiment of present invention. More particularly, following the step illustrated in FIG. 7, embodiments of present invention provide forming a hard mask 610 on top of the dielectric layer 600. The hard mask 610 may be made by first forming an organic planarization layer (OPL) on top of the dielectric layer 600, and subsequently subjecting the OPL to a lithographic patterning process to create a mask pattern. As a non-limiting example, the hard mask 610 may include a first opening 601 and a second opening 602 that are strategically placed to have a positional horizontal offset from the S/D regions that the openings are created to form respective contact metal for.

For example, as is illustrated in FIG. 8, the first opening 601 is positioned with a horizontal offset to the left from the S/D region 311 that the first opening 601 is created to form contact metal for. Similarly, the second opening 602 is positioned with a horizontal offset to the left as well from the S/D region 321 that the second opening 602 is created to form contact metal for. In one embodiment, the offset may be such that the opening may be formed at least partially underneath a nearby S/D region. For example, the first opening 601 may be formed partially underneath the S/D region 312 that is nearby the S/D region 311 that the first opening 601 is created for forming a metal contact.

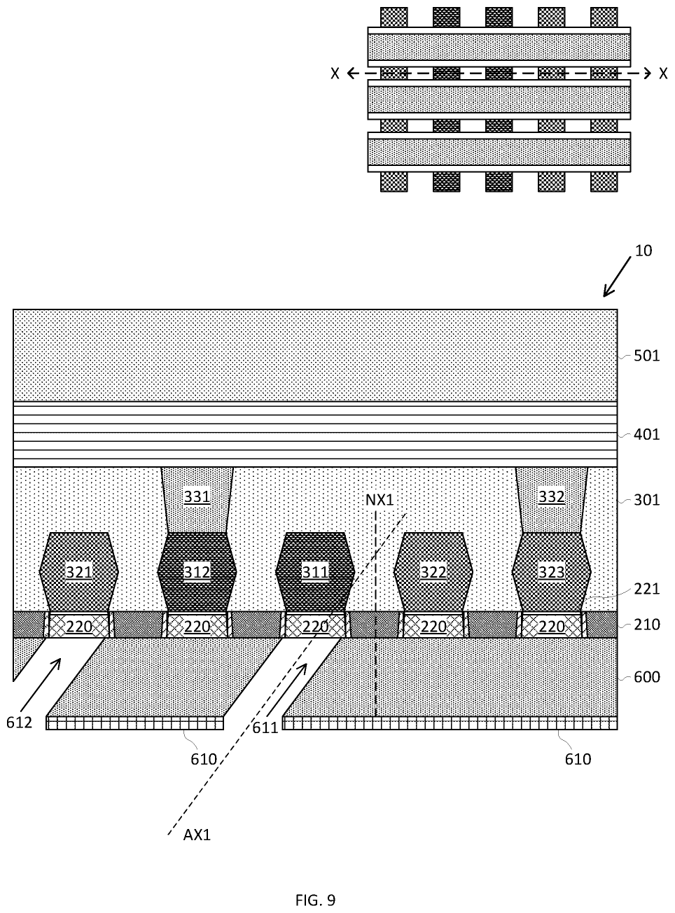

FIG. 9 is a demonstrative illustration of cross-sectional view of a semiconductor structure in a step of manufacturing thereof according to one embodiment of present invention. More particularly, following the step illustrated in FIG. 8, embodiments of present invention provide performing a selective anisotropic etch process, such a reactive-ion-etch (RIE) process in an angled direction, to create a first set of angled openings in the dielectric layer 600. For example, a first angled opening 611 may be made through the first opening 601 in the dielectric layer 600 and a second angled opening 612 may be made through the second opening 602 in the dielectric layer 600. The first angled opening 611 may expose one of the placeholders 220 underneath the S/D region 311 and the second angled opening 612 may expose one of the placeholders 220 underneath the S/D region 321.

The first set of angled openings may have a longitudinal axis AX1 along directions of the respective first and second angled openings 611 and 612 and the longitudinal axis AX1 may form an angle with a normal NX1 of the dielectric layer 600. The angle between the longitudinal axis AX1 and the normal NX1 may be, for example, between about 5 degrees and about 45 degrees.

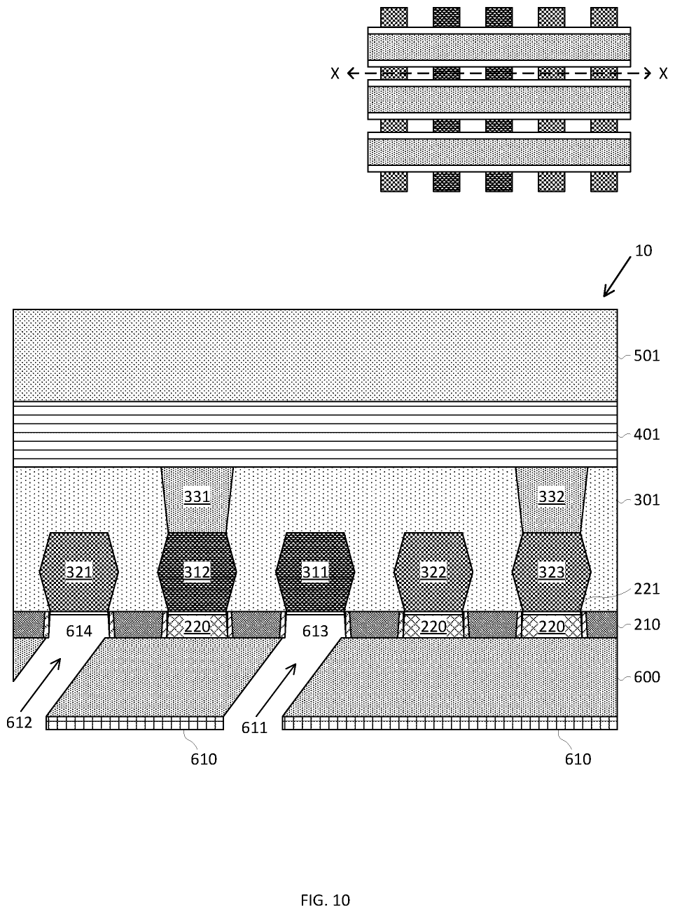

FIG. 10 is a demonstrative illustration of cross-sectional view of a semiconductor structure in a step of manufacturing thereof according to one embodiment of present invention. More particularly, following the step illustrated in FIG. 9, embodiments of present invention provide removing the placeholders 220 exposed by the first and the second angled openings 611 and 612 to expose a bottom surface of the S/D region 311 associated with the first angled opening 611 and a bottom surface of the S/D region 321 associated with the second angled opening 612. By strategically applying the difference in etch selectivity due to material difference, the placeholders 220 of SiGe, for example, may be selectively removed or etched away in an isotropic etch process relative to the liner 211 and the dielectric layer 600. In the meantime, the etch-stop layer 221 of Si epi layer may protect the S/D regions 311 and 321 during the selective removal process of the placeholders 220.

The removal of the placeholders 220 may create opening extensions between the S/D regions and the angled openings. For example, a first opening extension 613 may be created between the S/D region 311 and the first angled opening 611 and a second opening extension 614 may be created between the S/D region 321 and the second angled opening 612.

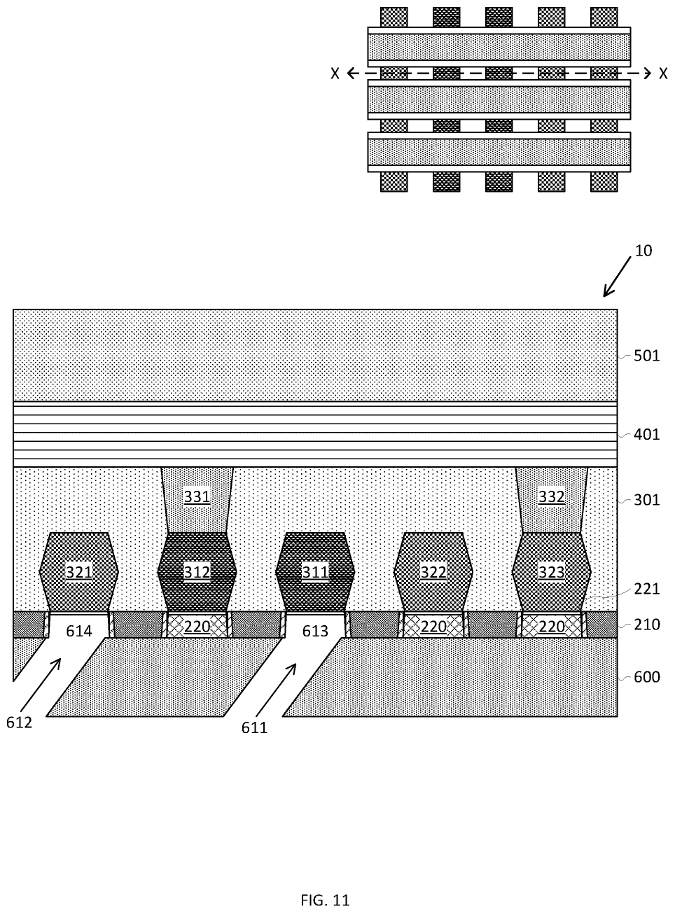

FIG. 11 is a demonstrative illustration of cross-sectional view of a semiconductor structure in a step of manufacturing thereof according to one embodiment of present invention. More particularly, following the step illustrated in FIG. 10, embodiments of present invention provide removing the hard mask 610 from the dielectric layer 600 in preparation for forming a second set of angled openings in the dielectric layer 600. Removing the hard mask 610 may be made through, for example, a dry ash process or other lifting process.

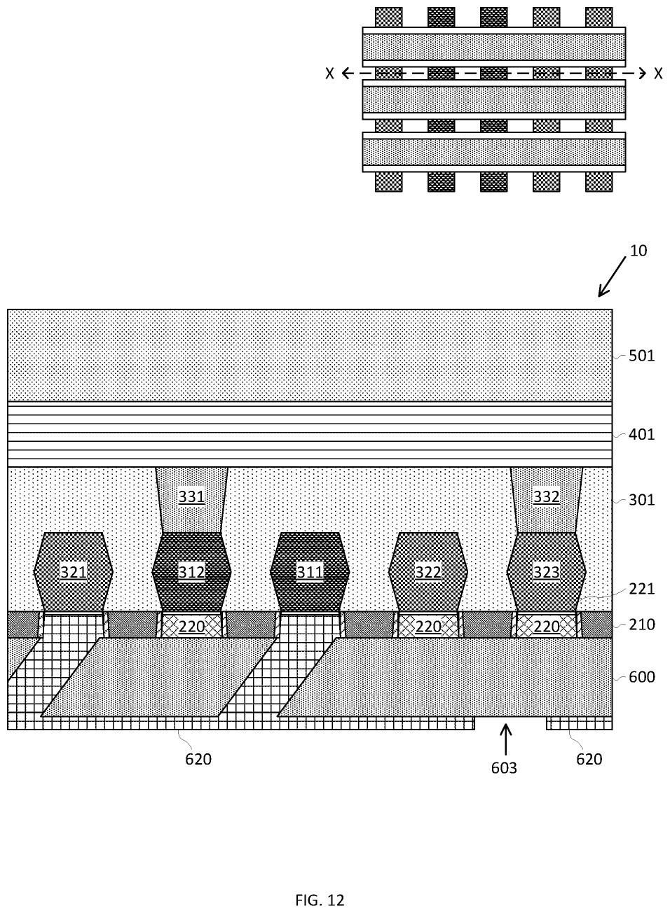

FIG. 12 is a demonstrative illustration of cross-sectional view of a semiconductor structure in a step of manufacturing thereof according to one embodiment of present invention. More particularly, following the step illustrated in FIG. 11, embodiments of present invention provide forming a hard mask 620 on top of the exposed dielectric layer 600. The hard mask 620 may include one or more openings, such as a third opening 603, that are strategically placed to have a positional horizontal offset from the S/D regions that the openings are created for forming metal contacts. For example, as is illustrated in FIG. 12, the third opening 603 is positioned with a horizontal offset to the right from the S/D region 322 that the third opening 603 is created for forming a metal contact. In one embodiment, the offset may be such that the opening may be formed at least partially underneath a nearby S/D region. For example, the third opening 603 may be formed partially underneath the S/D region 323 that is nearby the S/D region 322. The hard mask 620 may also fill, thereby protect the first set of angled openings such as the first angled opening 611 and the second angled opening 612 created so far.

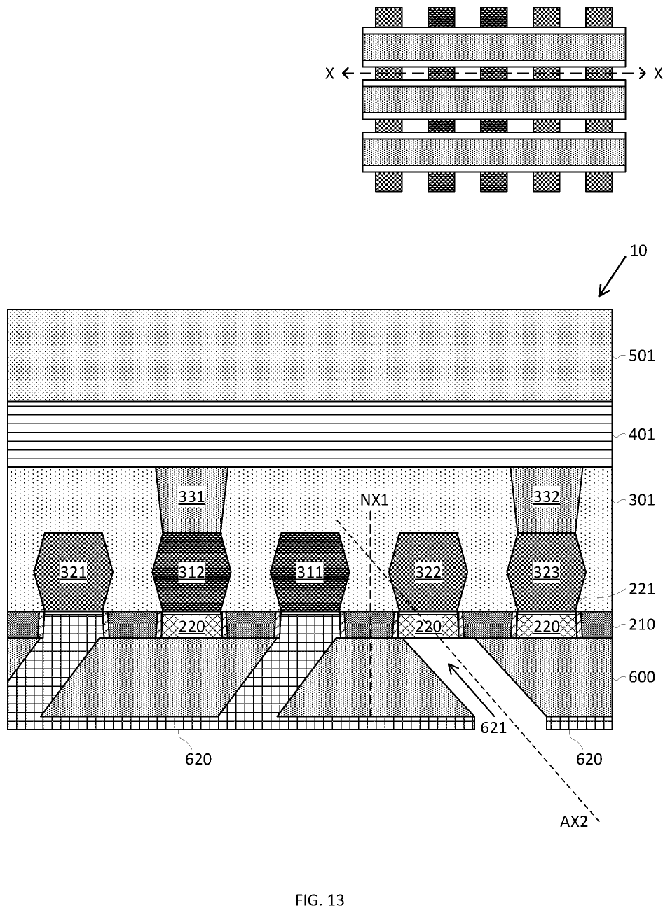

FIG. 13 is a demonstrative illustration of cross-sectional view of a semiconductor structure in a step of manufacturing thereof according to one embodiment of present invention. More particularly, following the step illustrated in FIG. 12, embodiments of present invention provide performing a selective etch process, such a RIE process in an angled direction, to create a second set of angled openings in the dielectric layer 600. For example, a third angled opening 621 may be made through the third opening 603 in the dielectric layer 600. The third angled opening 621 may expose the placeholder 220 underneath the S/D region 322.

The second set of angled openings may have a longitudinal axis AX2 along directions of the respective angled openings such as the third angled opening 621 and the longitudinal axis AX2 may form an angle with the normal NX1 of the dielectric layer 600. The angle may be, for example, between about-5 degrees and about-45 degrees.

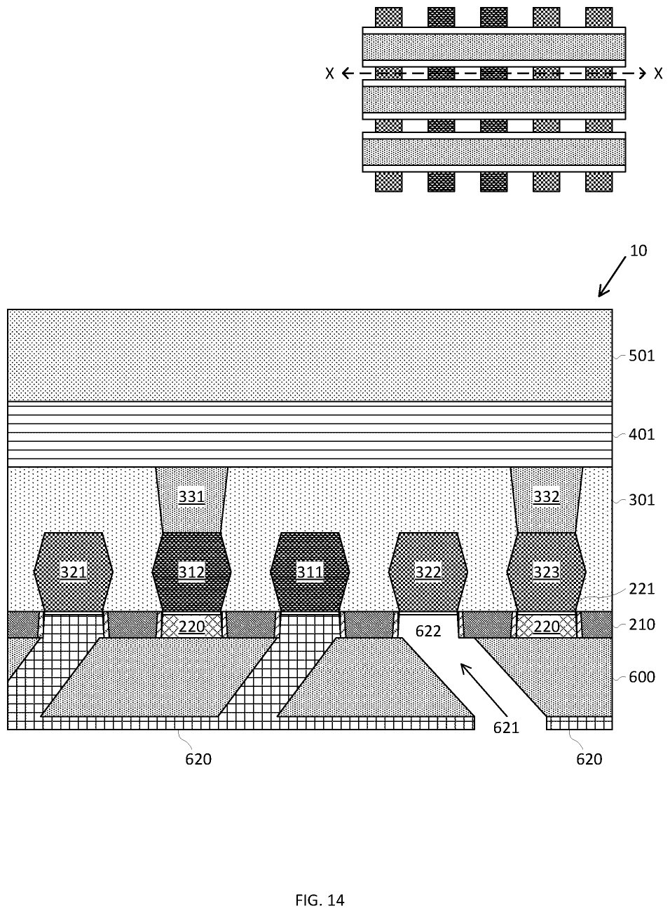

FIG. 14 is a demonstrative illustration of cross-sectional view of a semiconductor structure in a step of manufacturing thereof according to one embodiment of present invention. More particularly, following the step illustrated in FIG. 13, embodiments of present invention provide removing the placeholders 220 exposed by the third angled opening 621 to expose a bottom surface of the S/D region 322 associated with the third angled opening 621. By strategically applying the difference in etch selectivity, the placeholders 220 may be selectively removed or etched away relative to the liner 211 and the dielectric layer 600 while the etch-stop layer 221 protects the S/D region 322 during the selective removal process. The removal of the placeholders 220 may create a third opening extension 622 between the S/D region 322 and the third angled opening 621.

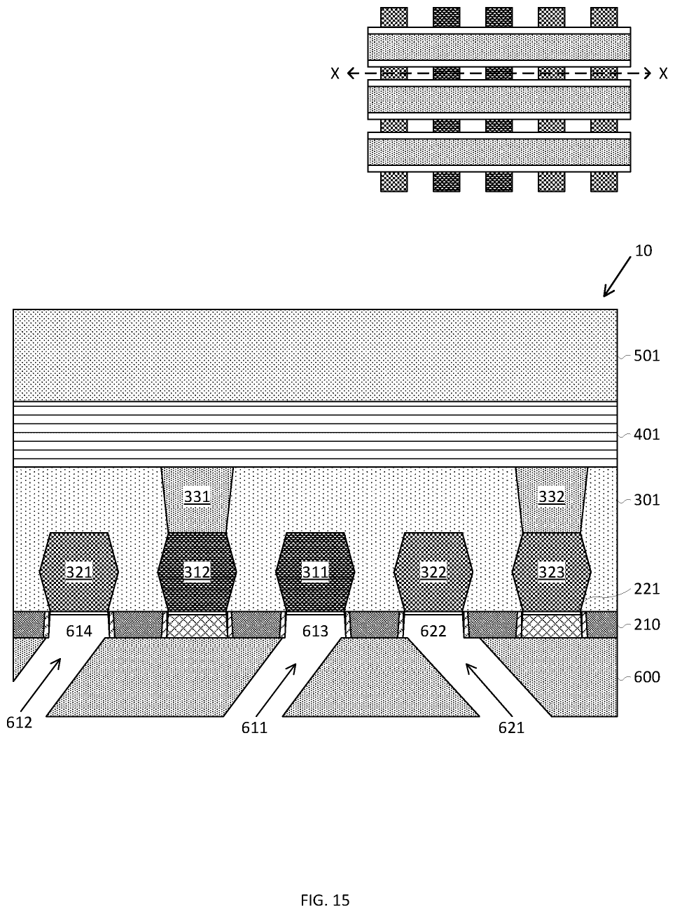

FIG. 15 is a demonstrative illustration of cross-sectional view of a semiconductor structure in a step of manufacturing thereof according to one embodiment of present invention. More particularly, following the step illustrated in FIG. 14, embodiments of present invention provide removing the hard mask 620 from the dielectric layer 600. Removal of the hard mask 620 may also remove the hard mask material from the first and the second angled openings 611 and 612 and from the first and the second opening extensions 613 and 614 to expose the bottom surfaces of the S/D regions 311 and 321.

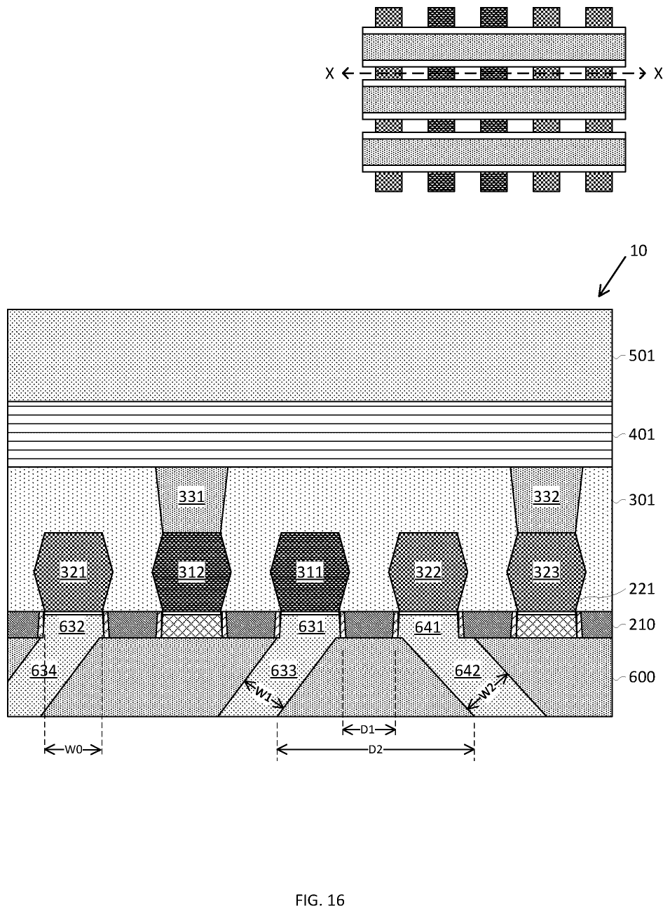

FIG. 16 is a demonstrative illustration of cross-sectional view of a semiconductor structure in a step of manufacturing thereof according to one embodiment of present invention. More particularly, following the step illustrated in FIG. 15, embodiments of present invention provide filling the first, second, and third opening extensions 613, 614 and 622 with a conductive material such as copper (Cu), tungsten (W), ruthenium (Lu), cobalt (Co), or other suitable material to form a first backside S/D contact 631, a second backside S/D contact 632, and a third backside S/D contact 641. The first, second, and third backside S/D contacts 631, 632, and 641 may be surrounded at sidewalls by the liner 211 and may be substantially aligned with the S/D regions 311, 321, and 322 on top thereof respectively. The first, second, and third backside S/D contacts 631, 632, and 641 may be self-aligned to the S/D regions 311, 321, and 322 because the S/D regions 311, 321, and 322 were formed in a self-aligned manner to the (now removed) placeholders 220.

Embodiments of present invention may provide continuing to fill the angled openings such as the first, second, and third angled openings 611, 612, and 621 with the same conductive material, or alternatively a different conductive material, to form one or more backside contact metal (BCM) such as a first BCM 633, a second BCM 634, and a third BCM 642. The first and the second BCM 633 and 634 lean towards right side, following the orientation of their respective first and second angled openings 611 and 612 to have a first longitudinal axis AX1 (see FIG. 9). On the other hand, the third BCM 642 leans towards left side, following the orientation of the third angled opening 621 to have a second longitudinal axis AX2 (see FIG. 13). The first longitudinal axis AX1 intersects with the second longitudinal axis AX2 and forms an acute angle, i.e., an angle between 0 and 90 degrees, with the second longitudinal axis AX2.

In one embodiment, the first BCM 633 may have a first width W1 measured in a direction perpendicular to the first longitudinal axis AX1 and the first width W1 may not be equal to and may be smaller or larger than a horizontal width W0 of the first backside S/D contact 631. Similarly, the third BCM 642 may have a second width W2 measured in a direction perpendicular to the second longitudinal axis AX2 and the second width W2 may be, for example, made larger than a horizontal width W0 of the third backside S/D contact 641. As is illustrated in FIG. 16, the first, second, and third backside S/D contacts 631, 632, and 641 are illustrated to have a same horizontal width W0. Having the width of the first and/or second BCM larger than the horizontal width of the associated S/D contact enables a reduction in contact resistance of the BCM, which is inversely proportional to the cross-sectional area of the BCM.

In another embodiment, the first and the third BCM 633 and 642 may extend into areas underneath S/D regions such as the S/D region 312 next to the S/D region 311 and the S/D region 323 next to the S/D region 322. Embodiments of present invention take advantage of the fact that contacts to the S/D regions 312 and 323 are made through the first and second frontside S/D contacts 331 and 332 such that regions underneath the S/D regions 312 and 323 are unused and thus may be used to form a first backside S/D contact structure, which may include the first backside S/D contact 631 and the first BCM 633, and a second backside S/D contact structure, which may include the third backside S/D contact 641 and the third BCM 642. The first and the second backside S/D contact structure may be separated by a distance D2 that is larger than a distance D1 between the first backside S/D contact 631 and the third backside S/D contact 641. The spreading of distance between the first and the second backside S/D contact structure ensures more flexibility of forming the S/D contacts and more spacings for forming backside power rails (BPRs), as being described below in more details.

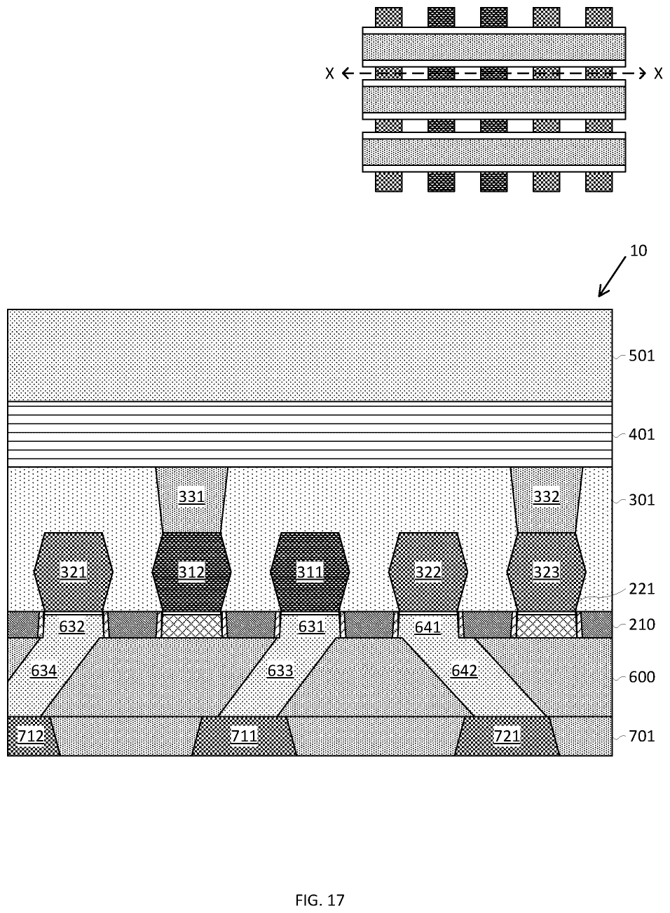

FIG. 17 is a demonstrative illustration of cross-sectional view of a semiconductor structure in a step of manufacturing thereof according to one embodiment of present invention. More particularly, following the step illustrated in FIG. 16, embodiments of present invention provide forming a dielectric layer 701 on top of the dielectric layer 600 covering the angled backside S/D contact structures, and one or more BPRs may be formed in the dielectric layer 701 to be in contact with the one or more BCMs of the angled backside S/D contact structures. For example, a first BPR 711 may be formed to be in contact with a bottom surface of the first BCM 633, a second BPR 712 may be formed to be in contact with a bottom surface of the second BCM 634, and a third BPR 721 may be formed to be in contact with a bottom surface of the third BCM 642.

As is demonstratively illustrated in FIG. 16 and FIG. 17, the first BPR 711 and the third BPR 721 may be able to maintain a wide spacing D2 while the first backside S/D contact 631 and the third backside S/D contact 641 maintain a relatively small spacing D1. As spacing D1 is generally defined in a self-aligned fashion, there is no electric shortage risk between the first and second backside S/D contact 631 and 641. On the other hand, spacing between neighboring BPRs is usually defined through a lithographic pattering process. In the case where spacing between the neighboring BPRs is small, there is a risk of electrical short between, for example, the first BPR 711 and the third BPR 721. By expanding the spacing to a wider distance D2, the risk of electrical short is significantly reduced and consequently device yield gets improved.

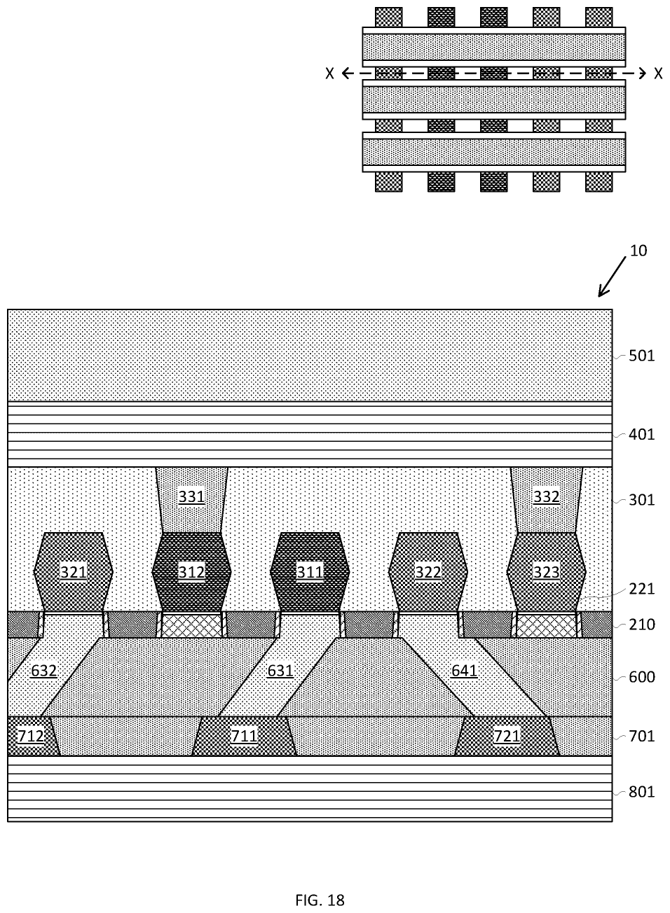

FIG. 18 is a demonstrative illustration of cross-sectional view of a semiconductor structure in a step of manufacturing thereof according to one embodiment of present invention. More particularly, following the step illustrated in FIG. 17, embodiments of present invention provide forming a backside power distribution network (BSPDN) 801 on top of the dielectric layer 701 to be in contact with the first, second, and third BPRs 711, 712, and 721.

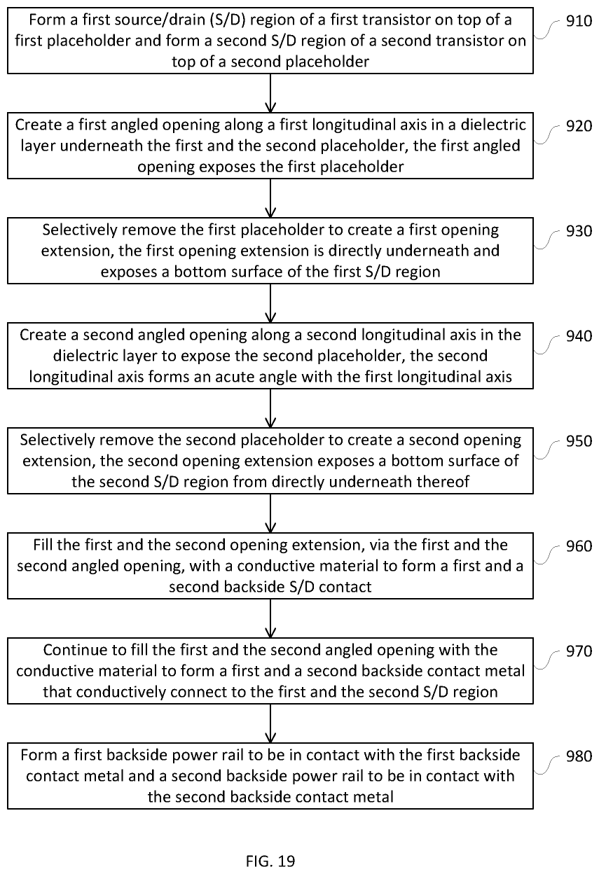

FIG. 19 is a demonstrative illustration of a flow-chart of a method of manufacturing a semiconductor structure according to embodiments of present invention. The method includes (910) forming a first source/drain (S/D) region of a first transistor on top of a first placeholder and forming a second S/D region of a second transistor on top of a second placeholder; (920) creating a first angled opening along a first longitudinal axis in a dielectric layer underneath the first and the second placeholder, where the first angled opening exposes the first placeholder; (930) selectively removing the first placeholder to create a first opening extension, where the first opening extension is directly underneath and exposes a bottom surface of the first S/D region; (940) creating a second angled opening along a second longitudinal axis in the dielectric layer to expose the second placeholder, where the second longitudinal axis forms an acute angle with the first longitudinal axis; (950) selectively removing the second placeholder to create a second opening extension, the second opening extension exposes a bottom surface of the second S/D region from directly underneath thereof; (960) filling the first and the second opening extension, via the first and the second angled opening, with a conductive material to form a first and a second backside S/D contact; (970) continuing to fill the first and the second angled opening with the conductive material to form a first and a second backside contact metal that conductively connect to the first and the second S/D region; and (980) forming a first backside power rail to be in contact with the first backside contact metal and a second backside power rail to be in contact with the second backside contact metal.

Various examples may possibly be described by one or more of the following features in the following numbered clauses:

Clause 1: A semiconductor structure comprising a first source/drain (S/D) region of a first transistor and a second S/D region of a second transistor; a first backside contact metal (BCM) conductively connected to the first S/D region, the first BCM having a first longitudinal axis; and a second BCM conductively connected to the second S/D region, the second BCM having a second longitudinal axis, wherein the first longitudinal axis of the first BCM intersects with the second longitudinal axis of the second BCM in an acute angle.

Clause 2: The semiconductor structure of clause 1, wherein the first BCM is conductively connected to the first S/D region via a first backside S/D contact, the first backside S/D contact having a liner at sidewalls thereof and having a horizontal width that is substantially same as a bottom width of the first S/D region.

Clause 3: The semiconductor structure of clause 2, wherein the first BCM has a first width measured in a direction perpendicular to the first longitudinal axis, the first width being equal to or larger than the horizontal width of the first backside S/D contact.

Clause 4: The semiconductor structure of clause 2, wherein the first and the second BCM are embedded in a dielectric layer, the first longitudinal axis of the first BCM forming a first angle with a normal of the dielectric layer between 5 and 45 degrees, and the second longitudinal axis of the second BCM forming a second angle with the normal of the dielectric layer between −5 and −45 degrees.

Clause 5: The semiconductor structure of clause 2, wherein the first BCM is in contact with a first backside power rail (BPR) and the second BCM is in contact with a second BPR, a distance between the first and the second BPR is larger than a distance between the first and the second S/D region.

Clause 6: The semiconductor structure of clause 1, further comprising a third S/D region of a third transistor next to the first S/D region of the first transistor, the third S/D region being on top of a placeholder, the placeholder being materially different from the first backside S/D contact.

Clause 7: The semiconductor structure of clause 6, further comprising a frontside S/D contact contacting the third S/D region of the third transistor.

Clause 8: The semiconductor structure of clause 1, wherein the first S/D region comprises phosphorus-doped epitaxial silicon, and the second S/D region comprises boron-doped epitaxial silicon-germanium.

Clause 9: A method of forming a semiconductor structure comprising forming a first source/drain (S/D) region on top of a first placeholder and a second S/D region on top of a second placeholder; creating a first angled opening in a dielectric layer underneath the first and the second placeholder, the first angled opening exposing the first placeholder; selectively removing the first placeholder to create a first opening extension that exposes a bottom surface of the first S/D region; filling the first opening extension with a conductive material to form a first backside S/D contact; and filling the first angled opening with the conductive material to form a first backside contact metal (BCM) conductively connected to the first S/D region via the first backside S/D contact.

Clause 10: The method of clause 9, further comprising creating a second angled opening in the dielectric layer to expose the second placeholder; selectively removing the second placeholder to create a second opening extension that exposes a bottom surface of the second S/D region; filling the second opening extension to form a second backside S/D contact; and filling the second angled opening to form a second BCM conductively connected to the second S/D region via the second backside S/D contact, wherein the first BCM has a first longitudinal axis and the second BCM has a second longitudinal axis, the first and the second longitudinal axis form an acute angle.

Clause 11: The method of clause 9, wherein the dielectric layer is deposited on top of the first and the second placeholder after a set of raw placeholders are polished to create the first and the second placeholder.

Clause 12: The method of clause 9, wherein creating the first angled opening in the dielectric layer comprises forming a hard mask on top of the dielectric layer, the hard mask having a mask opening, the mask opening having a horizontal positional offset from the first placeholder; and etching the dielectric layer in an anisotropic etch process to create the first angled opening, the first angled opening being oriented in a direction connecting the mask opening with the first placeholder.

Clause 13: The method of clause 12, wherein a longitudinal axis of the first angled opening forms an angle between about 5 to 45 degrees with a normal of the dielectric layer.

Clause 14: The method of clause 9, further comprising forming a first backside power rail (BPR) in contact with the first BCM and a second BPR in contact with the second BCM.

Clause 15: The method of clause 9, further comprising forming a third S/D region of a third transistor on top of a third placeholder and next to the first S/D region, and forming a fourth S/D region of a fourth transistor on top of a fourth placeholder and next to the second S/D region, wherein the third S/D region is contacted by a first frontside S/D contact and the fourth S/D region is contacted by a second frontside S/D contact.

Clause 16: A semiconductor structure comprising a first source/drain (S/D) region of a first transistor on top of a first backside S/D contact; a second S/D region of a second transistor on top of a second backside S/D contact; a first backside contact metal (BCM) conductively connected to the first S/D region through the first backside S/D contact, the first BCM having a first longitudinal axis; and a second BCM conductively connected to the second S/D region through the second backside S/D contact, the second BCM having a second longitudinal axis, wherein the first longitudinal axis of the first BCM intersects with the second longitudinal axis of the second BCM in an angle between 10 and 90 degrees.

Clause 17: The semiconductor structure of clause 16, wherein the first backside S/D contact includes a liner at sidewalls thereof and has a horizontal width that is substantially same as a bottom width of the first S/D region.

Clause 18: The semiconductor structure of clause 17, wherein the first BCM have a first width in a direction perpendicular to the first longitudinal axis, the first width being equal to or larger than the horizontal width of the first backside S/D contact.

Clause 19: The semiconductor structure of clause 17, wherein the first BCM is in contact with a first backside power rail (BPR) and the second BCM is in contact with a second BPR, a distance between the first and the second BPR is larger than a distance between the first and the second S/D region.

Clause 20: The semiconductor structure of clause 16, further comprising a third S/D region of a third transistor next to the first S/D region of the first transistor and a frontside S/D contact contacting the third S/D region of the third transistor, the third S/D region being on top of a placeholder, the placeholder being materially different from the first backside S/D contact.

It is to be understood that the exemplary methods discussed herein may be readily incorporated with other semiconductor processing flows, semiconductor devices, and integrated circuits with various analog and digital circuitry or mixed-signal circuitry. In particular, integrated circuit dies can be fabricated with various devices such as field-effect transistors, bipolar transistors, metal-oxide-semiconductor transistors, diodes, capacitors, inductors, etc. An integrated circuit in accordance with the present invention can be employed in applications, hardware, and/or electronic systems. Suitable hardware and systems for implementing the invention may include, but are not limited to, personal computers, communication networks, electronic commerce systems, portable communications devices (e.g., cell phones), solid-state media storage devices, functional circuitry, etc. Systems and hardware incorporating such integrated circuits are considered part of the embodiments described herein. Given the teachings of the invention provided herein, one of ordinary skill in the art will be able to contemplate other implementations and applications of the techniques of the invention.

Accordingly, at least portions of one or more of the semiconductor structures described herein may be implemented in integrated circuits. The resulting integrated circuit chips may be distributed by the fabricator in raw wafer form (that is, as a single wafer that has multiple unpackaged chips), as a bare die, or in a packaged form. In the latter case the chip may be mounted in a single chip package (such as a plastic carrier, with leads that are affixed to a motherboard or other high-level carrier) or in a multichip package (such as a ceramic carrier that has surface interconnections and/or buried interconnections). In any case the chip may then be integrated with other chips, discrete circuit elements, and/or other signal processing devices as part of either an intermediate product, such as a motherboard, or an end product. The end product may be any product that includes integrated circuit chips, ranging from toys and other low-end applications to advanced computer products having a display, a keyboard or other input device, and a central processor.

The descriptions of various embodiments of present invention have been presented for the purposes of illustration and they are not intended to be exhaustive and present invention are not limited to the embodiments disclosed. The terminology used herein was chosen to best explain the principles of the embodiments, practical application or technical improvement over technologies found in the marketplace, and to enable others of ordinary skill in the art to understand the embodiments disclosed herein. Many modifications, substitutions, changes, and equivalents will now occur to those of ordinary skill in the art. Such changes, modification, and/or alternative embodiments may be made without departing from the spirit of present invention and are hereby all contemplated and considered within the scope of present invention. It is, therefore, to be understood that the appended claims are intended to cover all such modifications and changes as fall within the spirit of the invention.

What is claimed is:

1. A semiconductor structure comprising:
a first source/drain (S/D) region of a first transistor and a second S/D region of a second transistor;
a first backside contact metal (BCM) conductively connected to the first S/D region, the first BCM having a first longitudinal axis; and
a second BCM conductively connected to the second S/D region, the second BCM having a second longitudinal axis,
wherein the first longitudinal axis of the first BCM intersects with the second longitudinal axis of the second BCM in an acute angle.

2. The semiconductor structure of claim 1, wherein the first BCM is conductively connected to the first S/D region via a first backside S/D contact, the first backside S/D contact having a liner at sidewalls thereof and having a horizontal width that is substantially same as a bottom width of the first S/D region.

3. The semiconductor structure of claim 2, wherein the first BCM has a first width measured in a direction perpendicular to the first longitudinal axis, the first width being equal to or larger than the horizontal width of the first backside S/D contact.

4. The semiconductor structure of claim 2, wherein the first and the second BCM are embedded in a dielectric layer, the first longitudinal axis of the first BCM forming a first angle with a normal of the dielectric layer between 5 and 45 degrees, and the second longitudinal axis of the second BCM forming a second angle with the normal of the dielectric layer between −5 and −45 degrees.

5. The semiconductor structure of claim 2, wherein the first BCM is in contact with a first backside power rail (BPR) and the second BCM is in contact with a second BPR, a distance between the first and the second BPR is larger than a distance between the first and the second S/D region.

6. The semiconductor structure of claim 1, further comprising a third S/D region of a third transistor next to the first S/D region of the first transistor, the third S/D region being on top of a placeholder, the placeholder being materially different from the first backside S/D contact.

7. The semiconductor structure of claim 6, further comprising a frontside S/D contact contacting the third S/D region of the third transistor.

8. The semiconductor structure of claim 1, wherein the first S/D region comprises phosphorus-doped epitaxial silicon, and the second S/D region comprises boron-doped epitaxial silicon-germanium.

9. A method of forming a semiconductor structure comprising:
forming a first source/drain (S/D) region on top of a first placeholder and a second S/D region on top of a second placeholder;
creating a first angled opening in a dielectric layer underneath the first and the second placeholder, the first angled opening exposing the first placeholder;
selectively removing the first placeholder to create a first opening extension that exposes a bottom surface of the first S/D region;
filling the first opening extension with a conductive material to form a first backside S/D contact; and
filling the first angled opening with the conductive material to form a first backside contact metal (BCM) conductively connected to the first S/D region via the first backside S/D contact.

10. The method of claim 9, further comprising:
creating a second angled opening in the dielectric layer to expose the second placeholder;
selectively removing the second placeholder to create a second opening extension that exposes a bottom surface of the second S/D region;
filling the second opening extension to form a second backside S/D contact; and
filling the second angled opening to form a second BCM conductively connected to the second S/D region via the second backside S/D contact,
wherein the first BCM has a first longitudinal axis and the second BCM has a second longitudinal axis, the first and the second longitudinal axis form an acute angle.

11. The method of claim 9, wherein the dielectric layer is deposited on top of the first and the second placeholder after a set of raw placeholders are polished to create the first and the second placeholder.

12. The method of claim 9, wherein creating the first angled opening in the dielectric layer comprises:
forming a hard mask on top of the dielectric layer, the hard mask having a mask opening, the mask opening having a horizontal positional offset from the first placeholder; and
etching the dielectric layer in an anisotropic etch process to create the first angled opening, the first angled opening being oriented in a direction connecting the mask opening with the first placeholder.

13. The method of claim 12, wherein a longitudinal axis of the first angled opening forms an angle between about 5 to 45 degrees with a normal of the dielectric layer.

14. The method of claim 9, further comprising forming a first backside power rail (BPR) in contact with the first BCM and a second BPR in contact with the second BCM.

15. The method of claim 9, further comprising forming a third S/D region of a third transistor on top of a third placeholder and next to the first S/D region, and forming a fourth S/D region of a fourth transistor on top of a fourth placeholder and next to the second S/D region, wherein the third S/D region is contacted by a first frontside S/D contact and the fourth S/D region is contacted by a second frontside S/D contact.

16. A semiconductor structure comprising:
a first source/drain (S/D) region of a first transistor on top of a first backside S/D contact;
a second S/D region of a second transistor on top of a second backside S/D contact;
a first backside contact metal (BCM) conductively connected to the first S/D region through the first backside S/D contact, the first BCM having a first longitudinal axis; and
a second BCM conductively connected to the second S/D region through the second backside S/D contact, the second BCM having a second longitudinal axis,
wherein the first longitudinal axis of the first BCM intersects with the second longitudinal axis of the second BCM in an angle between 10 and 90 degrees.

17. The semiconductor structure of claim 16, wherein the first backside S/D contact includes a liner at sidewalls thereof and has a horizontal width that is substantially same as a bottom width of the first S/D region.

18. The semiconductor structure of claim 17, wherein the first BCM have a first width in a direction perpendicular to the first longitudinal axis, the first width being equal to or larger than the horizontal width of the first backside S/D contact.

19. The semiconductor structure of claim 17, wherein the first BCM is in contact with a first backside power rail (BPR) and the second BCM is in contact with a second BPR, a distance between the first and the second BPR is larger than a distance between the first and the second S/D region.

20. The semiconductor structure of claim 16, further comprising a third S/D region of a third transistor next to the first S/D region of the first transistor and a frontside S/D contact contacting the third S/D region of the third transistor, the third S/D region being on top of a placeholder, the placeholder being materially different from the first backside S/D contact.
